(19) United States
(12) Patent Application Publication
(10) Pub. No.: US 2010/0041239 A1
(43) Pub. Date: Feb. 18, 2010

(54) Diffractive Optical Element, Lithographic Apparatus and Semiconductor Device Manufacturing Method

(75) Inventor: Donis George FLAGELLO, Scottsdale, AZ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML Netherlands B.V., Veldhoven (NL)

(21) Appl. No.: 12/433,915

(22) Filed: May 1, 2009

Related U.S. Application Data
(60) Provisional application No. 61/089,667, filed on Aug. 18, 2008.

(51) Int. Cl. H01L 21/30; H01L 21/26; G02B 5/18; G02B 5/32; G03B 27/54

(52) U.S. Cl. 438/758; 438/795; 359/558; 359/15; 355/67; 257/E21.211; 257/E21.328

(57) ABSTRACT

A diffractive optical element, a lithographic apparatus including a diffractive optical element, and a semiconductor device manufacturing method diffract a radiation beam onto an output plane. The diffractive optical element has a plurality of unit cells each having a phase structure for adjusting a cross-sectional intensity distribution of an incoming radiation beam into a desired intensity distribution. The unit cells of the diffractive optical element have corresponding phase structures that are arranged adjacently and are mirrored or inverted with respect to each other.

### CROSS-REFERENCE TO RELATED APPLICATIONS

This application claims the benefit of U.S. Provisional Application No. 61/089,667, filed Aug. 18, 2008 by FLAGELLO, Donis George, the entire contents of which is incorporated by reference and for which priority is claimed under Title 35, United States Code §119(e).

### BACKGROUND

1. Field of Invention

The present invention relates to a diffractive optical element for use in a lithographic apparatus.

2. Description of Related Art

A lithographic apparatus applies a desired pattern onto a substrate, usually onto a target portion of the substrate. A lithographic apparatus can be used, for example, in the manufacture of integrated circuits (ICs). In that instance, a patterning device, which is alternatively referred to as a mask, may be used to generate a circuit pattern to be formed on an individual layer of the IC. This pattern can be transferred onto a target portion (e.g. including part of one or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction.

It is well-known in the art of lithography that an image of a mask pattern can be improved, and process windows enlarged, by appropriate choice of angles at which the mask pattern is illuminated. For example, in an apparatus having a Koehler illumination arrangement, an angular distribution of light illuminating the mask is determined by an intensity distribution in a pupil plane of a corresponding illumination system, which can be regarded as a secondary source. Illumination modes are commonly described by reference to a shape of the intensity distribution in the pupil plane. Conventional illumination, i.e., uniform illumination at all angles from zero to a certain maximum angle, requires a uniform disk-shaped intensity distribution in the pupil plane. Other commonly-used intensity distributions include: (i) annular, in which the intensity distribution in the pupil plane is an annulus; (ii) dipole illumination, in which there are two poles in the pupil plane; and (iii) quadrupole illumination, in which there are four poles in the pupil plane.

Various methods have been proposed to create these illumination schemes. For example, a zoom-axicon, i.e., a combination of a zoom lens and an axicon, can be used to create conventional illumination or annular illumination with controllable inner and outer radii (σᵢₙₙₑᵣ and σᵢₒᵤₜₑᵣ). Further, spatial filters can be used to create dipole- and quadrupole-type illumination modes. Spatial filters are opaque plates with apertures located where the poles are desired. However, using spatial filters is undesirable because the resulting loss of light reduces a throughput of the apparatus and hence, increases its cost of ownership.

It has, therefore, been proposed to use an optical element, e.g., a diffractive or refractive optical element, to form the desired intensity distribution in the pupil plane. For example, a diffractive optical element (DOE) can be used to generate multi-pole illumination modes, such as the quadrupole type. Such diffractive optical elements can include Fresnel lens segments for diffracting an incoming radiation beam. In other diffractive optical elements, diffraction of the incoming radiation beam is achieved by replacing the Fresnel lens segments with a computer-generated hologram. Such a computer-generated hologram is made of irregularly-patterned diffractive fringes. Diffractive optical elements can also made by etching the diffractive fringes into different parts of a surface of a quartz or CaF₂ substrate.

Typically, such diffractive optical elements include a plurality of unit cells, and each of the unit cells has the same irregularly patterned diffractive fringes. In such a diffractive optical element, each of the unit cells diffracts a portion of the incoming radiation beam into the required illumination mode. An advantage of a diffractive optical element having multiple unit cells is that the calculation of the required irregularly-patterned diffractive fringes is simpler and faster because of the smaller unit cell, when compared the full size of the diffractive optical element. However, a disadvantage of using such a diffractive optical element is that the uniformity of the intensity distribution of the radiation in the illumination mode may be too low for manufacturing specific ICs.

### SUMMARY

Given the foregoing, what is needed is a diffractive optical element capable of more uniformly redistributing an incoming radiation beam onto an output plane.

In an embodiment, an optical element diffracts a radiation beam having a first cross-sectional intensity distribution onto an output plane, such that the first cross-sectional distribution is spatially redistributed at the output plane into a second spatial intensity distribution. The optical element includes a first unit cell configured to diffract a first portion of the radiation beam into the second spatial intensity distribution and a second unit cell configured to diffract a second portion of the radiation beam into the second spatial intensity distribution. The first unit cell and the second unit cell are adjacently arranged on opposite sides of a first axis. The first unit cell has a first phase structure and the second unit cell has a second phase structure, and the second phase structure is an image of the first phase structure mirrored about the first axis.

In a further embodiment, a lithographic apparatus includes a support structure configured to support a pattern device that is configured to pattern a beam of radiation from an illumination system and a projection system configured to project the patterned beam towards a substrate support configured to support a substrate. The lithographic apparatus also includes an optical element for diffracting a radiation beam having a first cross-sectional intensity distribution onto an output plane, such that the first cross-sectional distribution is spatially redistributed at the output plane into a second spatial intensity distribution. The optical element includes a first unit cell configured to diffract a first portion of the radiation beam into the second spatial intensity distribution and a second unit cell configured to diffract a second portion of the radiation beam into the second spatial intensity distribution. The first unit cell and the second unit cell are adjacently arranged on opposite sides of a first axis. The first unit cell has a first phase structure and the second unit cell has a second phase structure, and the second phase structure is an image of the first phase structure mirrored about the first axis.

In a further embodiment, a semiconductor device manufacturing method coats at least a portion a substrate with a layer of radiation-sensitive material. A radiation beam having a first intensity distribution is generated. The first intensity distribution of the generated radiation beam is then modified to form a conditioned radiation beam having a second intensity distribution. The modifying step includes diffracting a first portion of the radiation beam using a first unit cell having a first phase structure into the second intensity distribution and diffracting a second portion of the radiation beam using a second unit cell having a second phase structure into the second intensity distribution. The second cell is arranged adjacently and on an opposite side of a first axis, and the second phase structure is an image of the first phase structure mirrored about the first axis. The conditioned radiation beam is patterned and projected onto a target portion of the substrate.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present invention and, together with the description, further serve to explain the principles of the invention and to enable a person skilled in the relevant art(s) to make and use the invention.

FIG. 1 schematically depicts a lithographic apparatus according to an embodiment of the present invention.

FIG. 2 schematically depicts an exemplary diffractive optical element diffracting a radiation beam onto an output plane, according to an embodiment of the present invention.

FIG. 3 schematically depicts an exemplary diffractive optical elements having a phase structure.

FIG. 4 schematically depicts an exemplary intensity distribution in an output plane.

FIG. 5 schematically depicts an exemplary unit cell of a diffractive optical element.

FIG. 6 schematically depicts an existing diffractive optical element that includes multiple unit cells.

FIG. 7 schematically depicts an exemplary diffractive optical element that includes multiple unit cells, according to an embodiment of the present invention.

FIG. 8 schematically depicts an exemplary phase structure of a unit cell of a diffractive optical element.

FIG. 9 schematically depicts a phase structure of an existing diffractive optical element.

FIG. 10 schematically depicts a phase structure of an exemplary diffractive optical element, according to an embodiment of the present invention.

FIG. 11 schematically depicts an exemplary diffractive optical element that includes multiple unit cells, according to an embodiment of the present invention.

FIG. 12a schematically depicts a desired intensity distribution in an output plane of a diffractive optical element.

FIG. 12b schematically depicts an intensity distribution in an output plane of an existing diffractive optical element.

FIG. 12c schematically depicts an intensity distribution in an output plane of an exemplary diffractive optical element, according to an embodiment of the present invention.

### DETAILED DESCRIPTION

The present invention is directed to a diffractive optical element, a lithographic apparatus including a diffractive optical element, and a semiconductor device manufacturing method diffract a radiation beam onto an output plane. This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

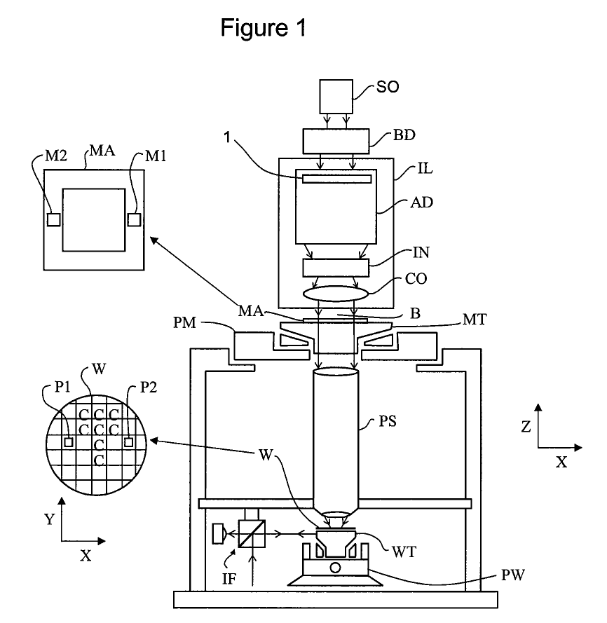

FIG. 1 schematically depicts a lithographic apparatus according to one embodiment of the invention. The lithographic apparatus includes an illumination system (illuminator) IL configured to condition a radiation beam B (e.g., UV radiation, DUV radiation, or EUV radiation). A support MT (e.g., a mask table) is configured to support a patterning device MA (e.g., a mask) and is connected to a first positioner PM that accurately positions the patterning device in accordance with certain parameters. A substrate table WT (e.g., a wafer table) is configured to hold a substrate W (e.g., a resist-coated wafer) and is connected to a second positioner PW that accurately positions the substrate in accordance with certain parameters. A projection system PS (e.g., a refractive projection lens system) is configured to project a pattern imparted to the radiation beam B by patterning device MA onto a target portion C (e.g., comprising one or more dies) of substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. Any use of the term “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in the target portion, such as an integrated circuit.

The patterning device may be transmissive or reflective. Examples of patterning devices include, but are not limited to, masks, programmable mirror arrays, and programmable LCD panels.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum.

The lithographic apparatus may be of a type having two (dual stage) or more substrate tables (and/or two or more mask tables). In such “multiple stage” machines, the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. Immersion techniques are well known in the art for increasing the numerical aperture of projection systems.

Referring to FIG. 1, illuminator IL receives a radiation beam from a radiation source SO. The source and the lithographic apparatus may be separate entities, for example when the source is an excimer laser. In such cases, the source is not considered to form part of the lithographic apparatus, and the radiation beam is passed from source SO to illuminator IL with the aid of a beam delivery system BD that includes, for example, suitable directing mirrors and/or a beam expander. In other cases, the source may be an integral part of the lithographic apparatus, for example when the source is a mercury lamp. Source SO and illuminator IL, together with beam delivery system BD if required, may be referred to as a “radiation system.”

Illuminator IL includes an adjuster AD for adjusting the angular intensity distribution of the radiation beam. The adjuster includes at least one diffractive optical element (DOE) 1 for adjusting an intensity distribution of the radiation beam in a pupil plane of illuminator IL. Additionally, the adjuster may include further optical elements for adjusting the intensity distribution of the radiation beam, such as a zoom-axicon. In addition, illuminator IL may include various other components, such as an integrator IN and a condenser CO. The illuminator may be used to condition the radiation beam to generate a conditioned beam having a desired uniformity and intensity distribution in its cross-section.

Radiation beam B is incident on the patterning device (e.g., mask MA), which is held on the support structure (e.g., mask table MT), and is patterned by the patterning device. Having traversed mask MA, beam B passes through projection system PS, which focuses the beam onto a target portion C of substrate W. With the aid of second positioner PW and a position sensor IF (e.g. an interferometric device, linear encoder or capacitive sensor), substrate table WT can be moved accurately, e.g. so as to position different target portions C in the path of radiation beam B. Similarly, first positioner PM and another position sensor (which is not explicitly depicted in FIG. 1) can be used to accurately position mask MA with respect to the path of radiation beam B, e.g. after mechanical retrieval from a mask library, or during a scan. In general, movement of mask table MT may be realized with the aid of a long-stroke module (coarse positioning) and a short-stroke module (fine positioning), which form part of first positioner PM. Similarly, movement of substrate table WT may be realized using a long-stroke module and a short-stroke module, which form part of second positioner PW. In the case of a stepper (as opposed to a scanner) mask table MT may be connected to a short-stroke actuator only, or may be fixed. Mask MA and substrate W may be aligned using mask alignment marks M1 and M2 and substrate alignment marks P1 and P2. Although the substrate alignment marks as illustrated occupy dedicated target portions, they may be located in spaces between target portions (these are known as scribe-lane alignment marks). Similarly, in situations in which more than one die is provided on mask MA, the mask alignment marks may be located between the dies.

The depicted apparatus could be used in at least one of the following modes:

1. In step mode, mask table MT and substrate table WT are kept essentially stationary, while an entire pattern imparted to the radiation beam is projected onto a target portion C at one time (i.e. a single static exposure). Substrate table WT is then shifted in the X and/or Y direction so that a different target portion C can be exposed. In step mode, the maximum size of the exposure field limits the size of target portion C imaged in a single static exposure.

2. In scan mode, mask table MT and substrate table WT are scanned synchronously while a pattern imparted to the radiation beam is projected onto a target portion C (i.e. a single dynamic exposure). A velocity and direction of substrate table WT relative to mask table MT may be determined by the magnification (or de-magnification) and image reversal characteristics of projection system PS. In scan mode, a maximum size of the exposure field limits the width (in the non-scanning direction) of the target portion in a single dynamic exposure, whereas the length of the scanning motion determines the height (in the scanning direction) of the target portion.

3. In another mode, mask table MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

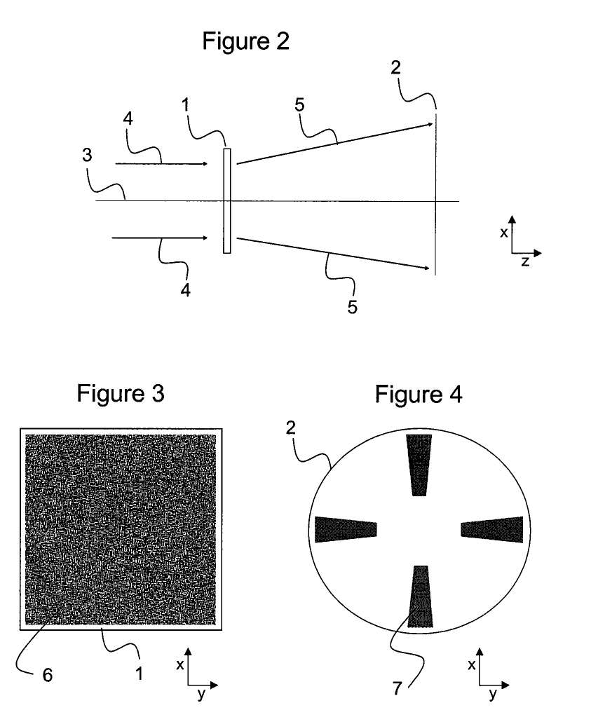

FIG. 2 schematically depicts an exemplary diffractive optical element 1, according to an embodiment of the present invention. In FIG. 2, diffractive optical element 1 diffracts an incoming radiation beam 4 onto an output plane 2. In an embodiment, the output plane 2 may be a pupil plane of an illuminator of a lithographic apparatus, as described above with reference to FIG. 1. In an embodiment, diffractive optical element 1 can be made out of quartz, CaF₂, or any other material that is sufficiently transparent to radiation having a wavelength of substantially 193 nm, 248 nm or 365 nm. As schematically depicted in FIG. 3, the diffractive optical element has a phase structure 6 for transforming a first intensity distribution of the incoming radiation beam into a second intensity distribution onto the output plane 2.

In an embodiment, the phase structure includes a computer-generated hologram (CGH). CGHs may be developed by calculating a desired holographic pattern and mathematically working backwards from that pattern, or reconstructed wavefront, to the particular hologram required. CGHs are generally surface-relief in nature, and CGHs can be formed using photolithography, etching, electron-beam writing, or any other technique, as would be apparent to one skilled in the art. For example, electron-beam technologies can form CGHs having resolutions close to that of optical film, but with amplitudes and phase quantization levels that are much coarser. Further, while photolithographic procedures can provide multilevel holograms, alignment errors between the respective layers increase with an increasing number of layers.

The second intensity distribution may be any distribution that is symmetric about at least one axis. FIG. 4 schematically depicts an intensity distribution 7 at the output plane 2 having 4 poles that are located equidistantly on the x-axis and y-axis. Other possible intensity distributions, also referred to as illumination modes, include dipole, annular, conventional, and any other illumination mode that is symmetric about at least one axis.

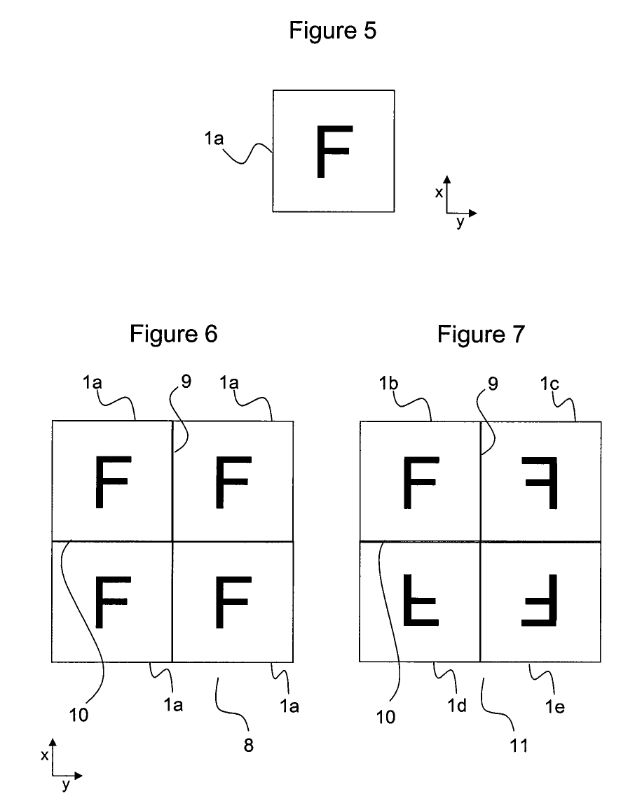

FIG. 5 schematically depicts a exemplary unit cell 1a of a diffractive optical element. In FIG. 5, a phase structure of unit cell 1 is represented by a letter “F” for explanatory purposes only. FIG. 6 schematically depicts an existing diffractive optical element 8 that includes multiple unit cells, such as unit cell 1a of FIG. 5. In FIG. 6, diffractive optical element 8 is made from a single piece of optical material and includes identical unit cells 1a arranged adjacently in an array. Unit cells 1a contact each other along a first axis 9 and a second axis 10. Typically, such an existing diffractive optical element has a footprint of approximately 50 mm by 30 mm and includes unit cells having a footprint ranging from approximately 1 mm by 1 mm to approximately 3 mm by 3 mm. In operation, a radiation beam is incident on diffractive optical element 8 along the z-axis (not shown). Each of the unit cells 1a diffracts a portion of the incoming radiation beam into the required illumination mode. A phase structure of the unit cell 1a typically has a pattern that is asymmetric across the unit cell. The asymmetry of the phase structure causes discontinuities at the axes 9 and 10, where the phase structures of the unit cells are adjacently arranged.

The discontinuities at the boundaries 9 and 10 result in a loss of diffraction efficiency and an increase in unwanted zeroth-order radiation being transmitted by diffractive optical element 8.

FIG. 7 schematically depicts an exemplary diffractive optical element 11 that includes multiple unit cells, according to an embodiment of the present invention. In FIG. 7, diffractive optical element 11 includes unit cells 1b, 1c, 1d, and 1e arranged, respectively and adjacently, in an array. The unit cells contact each other along a first axis 9 and a second axis 10. The phase structure of the first unit cell 1b may be similar to that of the exemplary unit cell 1a depicted in FIG. 5, as indicated by the letter “F” in the unit cell.

In FIG. 7, second unit cell 1c is arranged adjacent to first unit cell 1b such that unit cell 1b and second unit cell 1c are arranged on opposite side of axis 9. Further, a phase structure of unit cell 1c is an image of the phase structure of first unit cell 1b mirrored about axis 9. Such an arrangement is depicted in FIG. 7 by the letter “F,” which is mirrored about axis 9. Due to the mirroring of the phase structure of second unit cell 1c and the adjacent arrangement of the first and second unit cells 1b and 1c along axis 9, the phase structure of first unit cell 1b progresses into the phase structure of second unit cell 1c without any discontinuities.

Further, third unit cell 1d is arranged adjacent to first unit cell 1b such that first unit cell 1b and third unit cell 1d are arranged on opposite sides of axis 10. A phase structure of third unit cell 1d is an image of the phase structure of first unit cell 1b mirrored about axis 10, as depicted in FIG. 7 by the letter “F” that is mirrored about a axis 10. Due to the mirroring of the phase structure of third unit cell 1d and the adjacent arrangement of the first and third unit cells 1b and 1d along axis 10, the phase structure of first unit cell 1b progresses into the phase structure of third unit cell 1d without any discontinuities.

Fourth unit cell 1e is arranged adjacent to second and third unit cells 1c and 1d, respectively. A phase structure of fourth unit cell 1e is an inverted image of the phase structure of first unit cell 1b, as depicted in FIG. 7 by an inverted image of the letter “F”. Further, the inverted phase structure of fourth unit cell 1e corresponds to the phase structure of third unit cell 1d mirrored about axis 9. Also, the inverted phase structure of fourth unit cell 1e corresponds to the phase structure of second unit cell 1b mirrored about axis 10. Since fourth unit cell 1e is arranged adjacent to second and third unit cells 1c and 1d along respectively axis 9 and 10, the phase structures of second and third unit cells 1c and 1d progress into the phase structure of fourth unit cell 1e without any discontinuities.

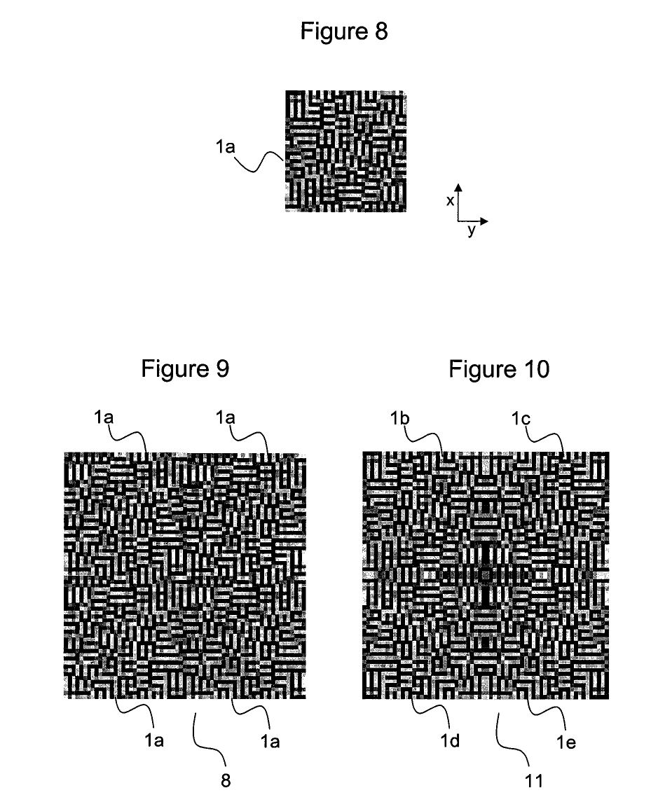

As mentioned above, the intensity distribution of the radiation beam on the output plane 2 as produced by unit cells 1a and 1b is symmetric about at least one axis. Since the phase structures of second and third unit cells 1c and 1d correspond to the mirrored phase structure of first unit cell 1b, an intensity distribution of the radiation beam on the output plane 2, as respectively produced by second and third unit cells 1c and 1d, is similar to the intensity distribution of the radiation beam on the output plane 2 produced by first unit cell 1b. Further, since the phase structure of fourth unit cell 1e corresponds to the inverted phase structure of first unit cell 1b, an intensity distribution of the radiation beam on the output plane 2 produced by fourth unit cell 1e is similar to the intensity distribution of the radiation beam on the output plane 2 produced by first unit cell 1b. Therefore, an overall intensity distribution at the output plane is similar to that as produced by existing diffractive optical element 8 of FIG. 6. However, when diffracting the radiation beam using exemplary diffractive optical element 11 of FIG. 7, no loss of diffraction efficiency and transmission of unwanted zeroth-order radiation occurs due to discontinuities of the phase structure at the boundaries of the unit cells where two unit cells are arranged adjacently. Such advantages are further illustrated in FIGS. 8, 9 and 10.

FIG. 8 schematically depicts a exemplary phase structure of a unit cell 1a of a diffractive optical element. In FIG. 8, the phase structure is asymmetric and represented by a grey scale pattern of large dimensions for explanatory purposes only.

In operation, the phase structure includes diffractive fringes that are etched into different parts of the surface of the diffractive optical element. These diffractive fringes may have dimensions on the order of several microns.

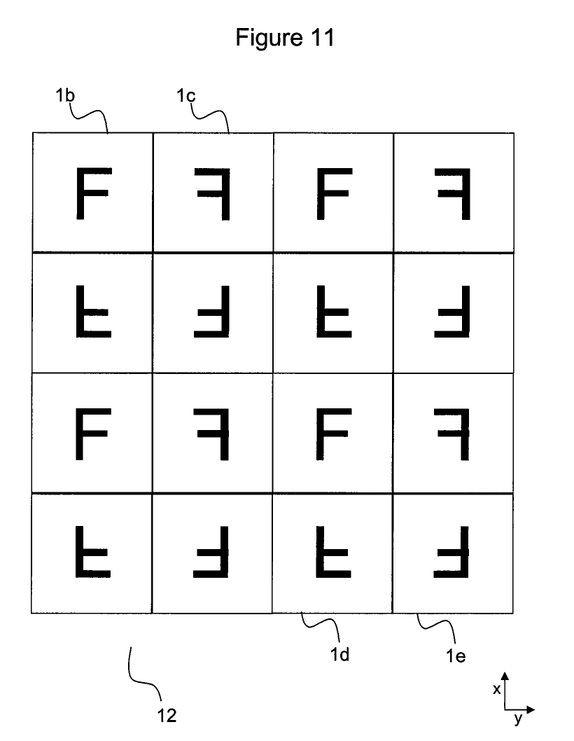

FIG. 9 schematically depicts a phase structure of an existing diffractive optical element 8 that includes four individual unit cells, e.g., unit cell 1a of FIG. 8, arranged adjacently in an array. FIG. 10 schematically depicts a phase structure of an exemplary diffractive optical element 11, according to an embodiment of the present invention. Diffractive optical element 11 includes four unit cells 1b, 1c, 1d, 1e. In an embodiment, unit cells 1b, 1c, 1d, 1e are similar to those described above in reference to FIG. 7. In the embodiment of FIG. 11, unit cell 1b and unit cell 1c are arranged adjacently and on opposite sides of a first axis (not shown), and a phase structure of unit cell 1c corresponds to the phase structure of unit cell 1b mirrored about that first axis. Further, unit cell 1b and unit cell 1d are arranged adjacently and at opposite sides of a second axis (not shown), and a phase structure of unit cell 1d corresponds to the phase structure of unit cell 1b mirrored about that second axis. Unit cell 1e is arranged adjacent to both unit cell 1e and unit cell 1d, and a phase structure of unit cell 1e corresponds to an inverted image of the phase structure of unit cell 1b. In FIG. 10, and in contrast to that depicted in FIG. 9, the asymmetric pattern of the phase structure extends without discontinuities across the boundaries of unit cells 1b, 1c, 1d and 1e (i.e., across the first and second axes).

In the embodiment of FIGS. 7 and 10, the diffractive optical element includes four unit cells. However, in alternative embodiments, the diffractive optical element can include only two unit cells. In such embodiment, the diffractive optical element would include a first unit cell 1b having a first phase structure and a second unit cell 1c arranged adjacent to first unit cell 1b at on a side of an axis opposite unit cell 1b. Second unit cell 1c would have a phase structure that corresponds to an image of the phase structure of the first unit cell 1b mirrored about that axis.

FIG. 11 schematically depicts an exemplary diffractive optical element 12 that includes a plurality of unit cells, according to an embodiment of the present invention. Diffractive optical element 12 includes unit cells 1b, 1c, 1d and 1e arranged such that a phase structure of diffractive optical element 12 extends across the boundaries of the respective unit cells without any discontinuities. Further, diffractive optical element 12 can include any number of unit cells, arranged in any combination of a square n by n array of unit cells or a rectangular n by m array of unit cells.

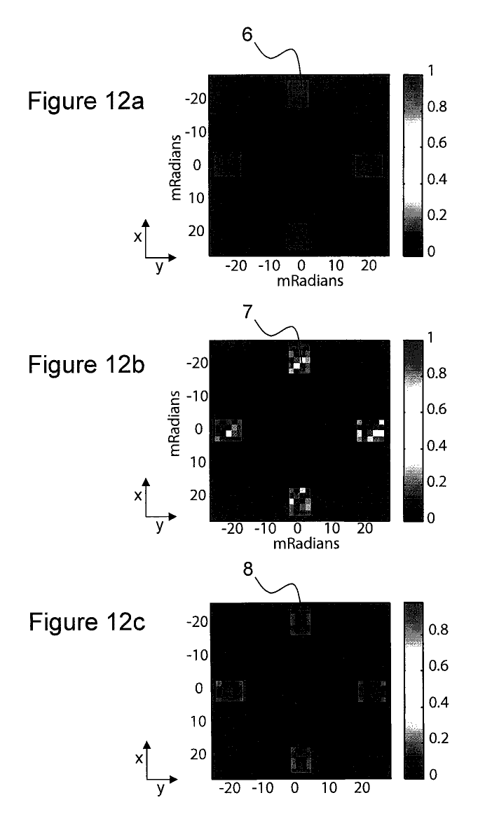

FIG. 12a schematically depicts a desired intensity distribution of a radiation beam at an output plane of a diffractive optical element. In FIG. 12a, the desired intensity distribution includes four poles, shown generally at 6, having an equal, uniform intensity. Further, for explanatory purposes, the desired intensity is shown normalized. FIG. 12b schematically depicts a simulated intensity distribution in an output plane of an existing diffractive optical element, e.g., existing diffractive optical element 8 of FIGS. 6 and 9. In the simulation of FIG. 12b, the existing diffractive optical element includes four unit cells that are arranged as depicted in FIG. 6.

In an embodiment, an incoming radiation beam has a cross-sectional size equal to that of the diffractive optical element and has a uniform intensity distribution. Further, to illustrate features of the present invention, an intensity distribution has been performed with a low sampling. FIG. 12c schematically depicts a simulated intensity distribution in an output plane of an exemplary diffractive optical element, according to an embodiment of the present invention. In the simulation of FIG. 12c, the exemplary diffractive optical element includes four unit cells that are arranged as depicted in FIG. 7. Further, all other simulation parameters are equal to those of the simulation of FIG. 12b. A comparison of the simulated intensity distributions of FIG. 12b with those of FIG. 12c indicates the diffractive optical element of the present invention results in a more uniform intensity distribution at an output plane than is obtained using the existing diffractive optical element.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

### CONCLUSION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. An optical element for diffracting a radiation beam having a first cross-sectional intensity distribution onto an output plane, wherein the first cross-sectional distribution is spatially redistributed at the output plane into a second spatial intensity distribution, comprising:
a first unit cell configured to diffract a first portion of the radiation beam into the second spatial intensity distribution; and
a second unit cell configured to diffract a second portion of the radiation beam into the second spatial intensity distribution, wherein:
the first unit cell and the second unit cell are adjacently arranged on opposite sides of a first axis;
the first unit cell has a first phase structure and the second unit cell has a second phase structure; and
the second phase structure is an image of the first phase structure mirrored about the first axis.

2. The optical element of claim 1, wherein one or more of the first phase structure and the second phase structure are a computer-generated hologram

3. The optical element of claim 1, further comprising:
a third unit cell configured to diffract a third portion of the radiation beam into the second spatial intensity distribution, wherein:
the first and third unit cells are arranged adjacently on opposite sides of a second axis, the second axis being orthogonal to the first axis; and
a phase structure of the third unit cell is an image of the first phase structure mirrored about the second axis.

4. The optical element of claim 3, wherein the third phase structure is a computer-generated hologram.

5. The optical element of claim 3, further comprising:
a fourth unit cell configured to diffract a fourth portion of the radiation beam into the second spatial intensity distribution, wherein:
the second and fourth unit cells are arranged adjacently on opposite sides of the second axis;
the third and fourth unit cells are arranged adjacently on opposite sides of the first axis; and
a phase structure of the fourth unit cell is an inverted image of the second phase structure.

6. The optical element of claim 5, wherein the phase structure of the fourth unit cell is a computer-generated hologram.

7. The optical element of claim 5, wherein the first, second, third and fourth unit cells form a first composite unit cell having a first composite phase structure.

8. The optical element of claim 7, further comprising:
one or more additional composite unit cells having respective first, second, third and fourth unit cells, wherein:
a composite phase structure of each of the additional composite unit cells is substantially identical to the first composite phase structure; and
the first composite unit cell and each of the additional composite unit cells are arranged in an array.

9. The optical element of claim 1, wherein the second spatial distribution is symmetric about one or more one axes.

10. The optical element of claim 9, wherein the second spatial distribution is symmetric about two axes.

11. A lithographic apparatus, comprising:
a support structure configured to support a pattern device that is configured to pattern a beam of radiation from an illumination system;
a projection system configured to project the patterned beam towards a substrate support configured to support a substrate; and
an optical element for diffracting a radiation beam having a first cross-sectional intensity distribution onto an output plane, wherein the first cross-sectional distribution is spatially redistributed at the output plane into a second spatial intensity distribution, the optical element comprising:
a first unit cell configured to diffract a first portion of the radiation beam into the second spatial intensity distribution; and
a second unit cell configured to diffract a second portion of the radiation beam into the second spatial intensity distribution, wherein:
the first unit cell and the second unit cell are adjacently arranged on opposite sides of a first axis;
the first unit cell has a first phase structure and the second unit cell has a second phase structure; and
the second phase structure is an image of the first phase structure mirrored about the first axis.

12. The lithographic apparatus of claim 11, wherein one or more of the first phase structure and the second phase structure are a computer-generated hologram.

13. The lithographic apparatus of claim 11, further comprising:
a third unit cell configured to diffract a portion of the radiation beam into the second spatial intensity distribution, wherein:
the first and third unit cells are arranged adjacently on opposite sides of a second axis, the second axis being orthogonal to the first axis; and
a phase structure of the third unit cell is an image of the first phase structure mirrored about the second axis.

14. The lithographic apparatus of claim 11, wherein the third phase structure is a computer-generated hologram.

15. The lithographic apparatus of claim 13, further comprising:
a fourth unit cell configured to diffract a fourth portion of the radiation beam into the second spatial intensity distribution, wherein:
the second and fourth unit cells are arranged adjacently on opposite sides of the second axis;
the third and fourth unit cells are arranged adjacently on opposite sides of the first axis; and
a phase structure of the fourth unit cell is an inverted image of the second phase structure.

16. The lithographic apparatus of claim 15, wherein the phase structure of the fourth unit cell is a computer-generated hologram.

17. The lithographic apparatus of claim 15, wherein the first, second, third and fourth unit cells form a first composite unit cell having a first composite phase structure.

18. The lithographic apparatus of claim 17, further comprising:
one or more additional composite unit cells having respective first, second, third and fourth unit cells, wherein:
a composite phase structure of each of the additional composite unit cells is substantially identical to the first composite phase structure; and
the first composite unit cell and each of the additional composite unit cells are arranged in an array.

19. The lithographic apparatus of claim 11, wherein the second spatial distribution is symmetric about one or more one axes.

20. The lithographic apparatus of claim 19, wherein the second spatial distribution is symmetric about two axes.

21. A semiconductor device manufacturing method, comprising:
coating at least a portion a substrate with a layer of radiation-sensitive material;
generating a radiation beam having a first intensity distribution;
modifying the first intensity distribution of the generated radiation beam to form a conditioned radiation beam having a second intensity distribution, wherein the modifying step comprises:
diffracting a first portion of the radiation beam using a first unit cell having a first phase structure into the second intensity distribution,
diffracting a second portion of the radiation beam using a second unit cell having a second phase structure into the second intensity distribution, the first cell and the second cell being arranged adjacently at opposite sides of a first axis, and the second phase structure being an image of the first phase structure mirrored about the first axis;
patterning the conditioned radiation beam; and
projecting the patterned radiation beam onto a target portion of the substrate.

22. A diffractive optical element for diffracting an incoming radiation beam having a first cross-sectional intensity distribution onto an output plane, wherein the first cross-sectional distribution is spatially redistributed at the output plane into a second spatial intensity distribution,
the diffractive optical element comprising at least a first and second unit cell having respectively a first and second phase structure for diffracting a portion of the incoming radiation beam into the second spatial intensity distribution,
the first and second unit cells being arranged adjacently at opposite sides of a first axis,
wherein the second phase structure corresponds to an about the first axis mirrored first phase structure.

23. The diffractive optical element of claim 22, further comprising a third unit cell having a third phase structure for diffracting a portion of the incoming radiation beam into the second spatial intensity distribution,
the first and third unit cells being arranged adjacently at opposite sides of a second axis orthogonal to the first axis,
wherein the third phase structure corresponds to an about the second axis mirrored first phase structure.

24. The diffractive optical element of claim 23, further comprising a fourth unit cell having a fourth phase structure for diffracting a portion of the incoming radiation beam into the second spatial intensity distribution,
the fourth unit cells being arranged adjacently to the second and third unit cell along respectively the second and first axis,
wherein the third phase structure corresponds to an inverted first phase structure.

25. The diffractive optical element of claim 24, wherein the first, second, third and fourth unit cell form a first constituent unit cell having a first constituent phase structure, the diffractive optical element comprising further constituent unit cells having the same first constituent phase structure,
wherein the first and further constituent unit cells are arranged adjacently in an array.

26. The diffractive optical element of claim 22, wherein the second spatial distribution is symmetric about at least one axis.

27. The diffractive optical element of claim 22, wherein the second spatial distribution is symmetric about two axes.

28. The diffractive optical element of claim 22, wherein the phase structure is a computer-generated hologram.

29. (canceled)

30. A semiconductor device manufacturing method comprising:
providing a substrate that is at least partially covered by a layer of radiation-sensitive material;
generating a radiation beam having a first intensity distribution;
changing the first intensity distribution into a second intensity distribution using a diffractive optical element to form a conditioned radiation beam,
the diffractive optical element diffracting a first portion of the radiation beam using a first unit cell having a first phase structure into the second intensity distribution,
the diffractive optical element diffracting a second portion of the radiation beam using a second unit cell having a second phase structure into the second intensity distribution,
the first and second unit cells being arranged adjacently at opposite sides of a first axis and wherein the second phase structure corresponds to an about the first axis mirrored first phase structure;
imparting a pattern to the conditioned radiation beam;
projecting the patterned radiation beam onto a target portion of the substrate.
